(19) United States
(12) Patent Application Publication
(10) Pub. No.: US 2007/0281494 A1
(43) Pub. Date: Dec. 6, 2007

(54) Transparent Contact And Method For The Production Thereof

(75) Inventor: Frank Dimroth, Freiburg (DE)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: Fraunhofer-Gesellschaft zur Forderung der angewandten Forschung e. V., Muenchen (DE)

(21) Appl. No.: 11/596,308

(22) PCT Filed: May 13, 2005
(86) PCT No.: PCT/EP05/05249

§ 371 Date: Jun. 15, 2007

(30) Foreign Application Priority Data
May 14, 2004 (DE) 10 2004 023 977.0

(51) Int. Cl. H01L 21/31

(52) U.S. Cl. 438/761; 428/548

(57) ABSTRACT

The invention relates to a method for producing a transparent, low-resistance contact on a substrate, a layer sequence consisting of a first layer, a second layer, and a third layer being applied to the substrate. According to the invention, the first layer consists of a material containing AlₙGa₁₋ₙ AsₘSb₁₋ₘ, and is covered, in pre-determined regions, by a layer containing InₓGa₁₋ₓAs_{y}Sb_{1-y}, and the regions of the second layer containing InₓGa₁₋ₓAs_{y}Sb_{1-y} are at least partially covered by a layer consisting of a metal or an alloy, the parameters x and y being between 0.9 and 1.0, the parameter n between 0.3 and 1, and the parameter m between 0.0 and 0.1.

The invention relates to a transparent contact and a method for its production. Such contacts are used in semiconductor elements, in particular in optoelectronic components.

In the past few years, a large number of semiconductor elements that work in the infrared spectral range between 1 and 10 μm have be developed and commercialized. Examples are thermophotovoltaic cells, photodetectors, gas sensors and laser and light diodes. These components usually consist of binary, ternary or quaternary connecting semiconductors of the third and fifth main group of the periodic table. Examples are gallium antimonide (GaSb), indium arsenide (InAs) or mixed crystals like GaₓIn₁₋ₓAs_{y}Sb_{1-y}. The material named last has direct band gaps between 0.1 eV and 0.7 eV as well as lattice constants between 6.06 Å and 6.48 Å.

All of these components have the same problem: on one hand, electrical current and, on the other hand, photons must be coupled or decoupled over the surface of the component. According to the state of the art, the coupling of the electrical current takes place via a metal contact, which may have low transfer resistance to the semiconductor material, but is not transparent for incoming or outgoing photons and causes a high reflection loss.

It is also known that certain connecting semiconductors, such as aluminum gallium antimonide are very poorly contacted through metallic contacts. Thus, in the aforementioned semiconductor material, directly applied metal contacts lead to high transfer resistances and adhesion problems.

It is known from C. A. Wang, R. K. Huang, D. A. Shiau, M. K. Connors, P. G. Murphy, P. W. O'Brien, A. C. Anderson, D. M. DePoy, G. Nichols and M. N. Palmisiano, Monolithically Series-Interconnected GaInAsSb/AlGaAsSb/GaSb Thermophotovoltaic Devices with an Internal Backsurface Reflector Formed by Wafer Boding, Appl. Phys. Lett. 83 (2003) 1286 as well as from C. W. Hitchcock, R. J. Gutmann, J. M. Borrego, I. B. Bhat and G. W. Charache, Antimonide-Based Devices for Thermophotovoltaic Applications, IEEE Trans. Electron. Devices 46 (1999) 2154 to provide thermophotovoltaic cells made of GaSb and GaInAsSb with a transparent AlGaAsSb layer and applying to it a heavily doped contact layer made of GaSb. The contact resistance and thus the electrical losses of the component can be decreased considerably through the large-area GaSb contact layer. However, the disadvantage of this embodiment is that the GaSb contact layer absorbs a part of the photons with a wavelength under 1720 nm. Minority charge carriers, which are reflected by the AlGaAsSb layer and are no longer needed for power generation in the thermophotovoltaic cell, are thereby created. Another disadvantage is that the GaSb contact layer applied to the entire surface increases the reflection of the incoming light. The optical efficiency factor of the cell is thus also decreased.

Normally, a highly doped, unstructured GaSb contact layer on a transparent barrier layer made of AlGaAsSb is also used for surface-emitting, long-wave lasers, such as GaSb-based quantum laser with wavelength >2 μm. Although the GaSb contact layer in this wavelength range hardly absorbs the emitted light, the result is optical reflection losses due to the low refraction index of AlGaAsSb compared to GaSb, which decreases the overall degree of efficiency of the component.

The object of the present invention is thus to specify a transparent, low-resistance contact, which reduces both optical reflection and absorption losses as well as electrical resistance losses. Furthermore, the object is also to specify an optoelectronic component, which has an increased degree of efficiency compared to the state of the art.

The object is solved in accordance with the invention by a method for producing a transparent, low-resistance contact on a substrate, a layer sequence consisting of a first layer, a second layer and a third layer being applied to the substrate, wherein the first layer is made of an AlₙGa₁₋ₙAsₘSb₁₋ₘ containing material, whereupon an InₓGa₁₋ₓAs_{y}Sb_{1-y} containing layer is applied in pre-determined regions and the InₓGa₁₋ₓAs_{y}Sb_{1-y} containing areas of the second layer are at least partially provided with a layer made of a metal or an alloy, wherein the parameters x and y are selected from the interval 0.9 to 1.0, the parameter n from the interval 0.3 to 1 and the parameter m from the interval 0.0 to 0.1.

The substrate used in accordance with the invention is a binary, ternary or quaternary compound of the third and fifth main group of the periodic table. Preferably, the substrate contains GaSb and/or InAs and/or GaInAsSb and/or AlGaAsSb. The substrate can thereby be made homogeneously of one material or one layer sequence can have several homo- or heteroepitaxically precipitated materials.

In accordance with the invention, it was determined that the electrical resistance between a metal contact and a semiconductor material can be decreased considerably, if the contact layer, which was created out of GaSb in accordance with the current state of the art, is made if a material containing InₓGa₁₋ₓAs_{y}Sb. At the same time, this material can also easily be applied to only one partial area of the semiconductor substrate so that the transmission of photons is not by the contact layer.

Even the contact in accordance with the invention uses an AlₙGa₁₋ₙAsₘSb₁₋ₘ barrier layer known in accordance with the invention in order to passivate the subjacent component structure. However, no low-resistance contacts can be produced on these barrier layers. Furthermore, the aluminum-containing barrier layer tends toward oxidation, whereby the adhesion and the transfer resistance of the contacts are deteriorated further.

Due to their band structure, the InₓGa₁₋ₓAs_{y}Sb_{1-y} containing contact layers suggested here allow improved contacting of the semiconductor substrate through the AlₙGa₁₋ₙAsₘSb₁₋ₘ barrier layer in comparison with the state of the art. Furthermore, ohmic contacts with very low resistance can be produced on the suggested material of the contact layer. Thus, for example, the level of the Schottky barrier of a gold contact on n-doped InAs is only 0.01 eV. Similarly good ohmic contacts can be realized on p-doped InAsSb through layer contacts made of Ti/Ni/Au. Thus, the overall electrical resistance in comparison with the state of the art is brought down and the degree of electrical efficiency of the components is increased, in particular in the case of high current density.

As another advantage of the contact layer in accordance with the invention, it is notable that the InₓGa₁₋ₓAs_{y}Sb_{1-y}-material can be produced in an n-conducting or p-conducting manner through doping materials. Silicon and/or sulfur and/or tellurium and/or carbon and/or magnesium and/or zinc and/or selenium are particularly suitable as doping materials.

A particularly simple electrical contacting of the contact layer is provided when a layer made of a metal or an alloy, which contains gold and/or titanium and/or platinum and/or nickel and/or palladium and/or zinc and/or silver and/or germanium, is applied to the contact layer.

Depending on the material selected for the InₓGa₁₋ₓAs_{y}Sb_{1-y}-contact layer, the specialist will select from the named metals that which ensures good ohmic contacts with low Schottky barrier levels. In particular, the specialist will take into consideration multi-layered contacts made of various named metals or alloys. For the production of an alloy contact, several metal layers can also be applied and subsequently tempered.

A particularly simple production process of the transparent contact in accordance with the invention results from an epitaxic precipitation of the AlₙGa₁₋ₙAsₘSb₁₋ₘ-containing barrier layer and/or the InₓGa₁₋ₓAs_{y}Sb_{1-y}-containing contact layer.

Due to the good corrodibility of the contact layer in comparison to the barrier layer, it is easy to subsequently remove the contact layer in pre-determined surface areas of the barrier layer. A wet and dry chemical etching process can thereby be used.

Thus, the already existing barrier layer can also serve as an etching stop layer. In accordance with method according to the invention, it is thus possible to easily and selectively remove the contact layer from the component surface. The always present losses according to the state of the art due to optical reflection on the barrier layer or due to the absorption of photons in the contact layer should thus be avoided as requested. The degree of optical efficiency of the semiconductor element according to the invention is thus also considerably increased in comparison to the state of the art.

The etching of the contact layer occurs in a preferred embodiment through an etching solution, which contains citric acid and/or hydrogen peroxide and/or water. Particularly preferred hereby is a solution, the first component of which contains citric acid and water in a ratio of 1:1, which in turn is mixed with hydrogen peroxide as two components in a ratio of 5:1.

Particularly advantageous is an embodiment, in which the surface areas of the barrier layer not covered by the contact layer are covered by a preferably dielectric anti-reflex layer. This layer further decreases the reflection of incoming and outgoing light and thus increases the degree of optical efficiency of the component. Furthermore, the barrier layer is protected from chemical attacks and oxidation by the anti-reflex layer.

It is particularly preferred that the properties of the anti-reflex layer are modified for the spectral requirements of the components. Particularly suitable materials for the dielectric anti-reflex layer contain TaOₓ and/or TiO₂ and/or MgF and/or ZnS and/or Al₂O₃ and/or SiN and/or SiOₓ. During the modification of the anti-reflex layer for the spectral properties, the specialist also takes into consideration a combination of several layers of different materials.

Without restricting the general idea of the invention, the invention will be explained below based on one exemplary embodiment:

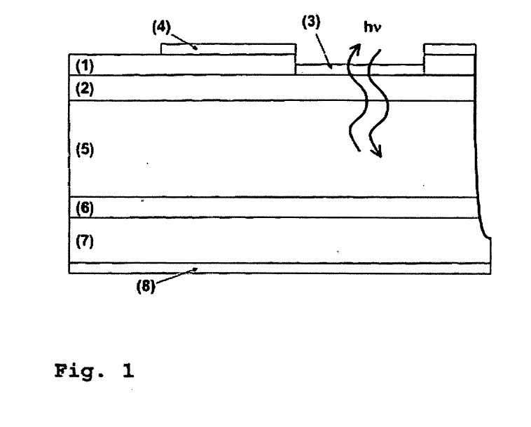

The thermophotovoltaic cell described as an example has an absorber layer structure 5 made of gallium antimonide (see FIG. 1). This absorber layer structure is applied in a known manner to a wafer 7, which is made of gallium antimonide. A buffer layer 6 arranged between the wafer surface and the absorber separated the active area of the component from the impurities always present on the wafer surface. A transparent barrier layer 2 made of Al_{0.6}Ga_{0.4}As_{0.02}Sb_{0.98} is epitaxically applied to the absorber layer structure. The thickness of the barrier layer 2 is thereby approx. 50 nm. In order to divert the created power, the component is provided with a 300-nm-thick contact layer 1 made of InAs_{0.98}Sb_{0.02}.

In a wet-chemical etching step, this contact layer 1 is removed again in partial areas of the component. The partial areas are thereby selected such that the entire degree of efficiency for the thermophotovoltaic application, which results from the degree of optical efficiency and the degree of electrical efficiency, is maximized. Here, 10.3% of the component surface is covered with the contact layer.

In order to further increase the degree of optical efficiency and in order to protect the barrier layer, a multi-layered antireflex layer 3 made of tantalum oxide and magnesium fluoride is applied to the free areas.

Another multi-layered metal contact 4 made of titanium, nickel and gold can be used for the low-loss contacting. A two-dimensional, metallic back-side contact 8 is applied to the back side of the wafer.

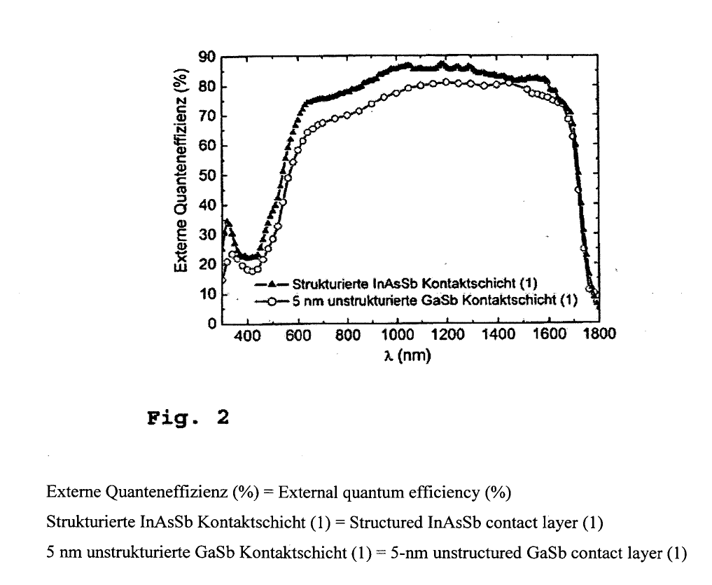

As shown in FIG. 2, the component produced in this manner reaches an off-load voltage of 370 mV and a short-circuit current density of 43 mA/cm².

In comparison, an identical gallium antimonide absorber layer 5 is provided with an Al_{0.6}Ga_{0.4}As_{0.02}Sb_{0.98} barrier layer 2 in the same manner. However, the contacting took place in accordance with the state of the art through a non-structured, non-transparent GaSb contact layer of 5 nm. In the case of lighting conditions that are identical with respect to light intensity and spectral composition, the component produced in this manner achieved an off-load voltage of only 316 mV and, in the case of a short circuit, a current density of 40 mA/cm².

In FIG. 2, the sensitivity of the component as an external quantum efficiency is represented in terms of the radiated wavelength. As desired, the degree of efficiency is increased in the range of 300 nm to 1600 nm through the structured contact layer according to the invention.

### LIST OF REFERENCES

1. Contact Layer
2. Barrier Layer
3. Anti-Reflex Layer
4. Metal or Alloy Layer
5. Absorber Layer/Substrate
6. Buffer Layer
7. Wafer
8. Back-Side Contact

1. A method for the production of a transparent, low-resistance contact on a substrate wherein, in the substrate, light can be converted into electrical energy and/or vice versa, comprising:
(i) applying a first layer to the substrate, wherein the first layer is made of an AlₙGa₁₋ₙAsₘSb₁₋ₘ containing material, the parameter n is from the interval 0.3 to 1 and the parameter in is from the interval 0.0 to 0.1,
(ii) applying a second layer to pre-determined regions of the first layer, wherein the second layer contains InₓGa₁₋ₓAs_{y}Sb_{1-y} and the parameters x and y are selected from the interval 0.9 to 1.0, and
(iii) applying at least partially a third layer to the second layer, wherein the third layer is made of a metal or an alloy.

2. The method according to claim 1, wherein the substrate contains GaSb, InAs, GaInAsSb, AlGaAsSb, or a combination thereof.

3. The method according to claim 1, wherein an anti-reflection layer made of a material containing a dielectricum is at least partially applied to the first layer in the areas that are not covered by the InₓGa₁₋ₓAs_{y}Sb_{1-y} containing second layer.

4. The method according to claim 3, wherein the anti-reflection layer is made of a material containing TaOₓ, TiO₂, MgF, ZnS, Al₂O₃, SiN, SiOₓ or a combination thereof.

5. The method according to claim 1, wherein the third layer is made of a material gold, titanium, platinum, nickel, palladium, zinc, silver, germanium, or a combination thereof.

6. The method according to claim 1, wherein at least one additional layer is applied to the third layer.

7. The method according to claim 6, wherein the third layer is tempered.

8. The method according to claim 3, wherein the InₓGa₁₋ₓAs_{y}Sb_{1-y} containing second layer is removed at least in the areas in which the anti-reflection layer is applied.

9. The method according to claim 8, wherein the InₓGa₁₋ₓAs_{y}Sb_{1-y} containing second layer is removed by etching.

10. The method according to claim 9, wherein the etching takes place through a citric acid and/or hydrogen peroxide and/or water-containing solution.

11. The method according to claim 1, wherein the AlₙGa₁₋ₙAsₘSb₁₋ₘ containing material of the first layer and/or the InₓGa₁₋ₓAs_{y}Sb_{1-y} containing material of the second layer is provided with a doping material.

12. The method according to claim 11, wherein the doping material is selected from silicon and/or sulfur and/or tellurium and/or carbon and/or magnesium and/or zinc and/or selenium.

13. The method according to claim 1, wherein the AlₙGa₁₋ₙAsₘSb₁₋ₘ containing material of the first layer and/or the InₓGa₁₋ₓAs_{y}Sb_{1-y} containing material of the second layer is epitaxically grown.

14. A transparent, low-resistance contact on a substrate wherein in the substrate light can be converted into electrical energy and/or vice versa, the contact comprising a layer sequence consisting of a first layer, a second layer and a third layer wherein:
the first layer contains AlₙGa₁₋ₙAsₘSb₁₋ₘ, the parameter n being selected from the interval 0.3 to 1 and the parameter m being selected from the interval 0.0 to 0.1,
the second layer is disposed over pre-determined regions of the first layer and contains InₓGa₁₋ₓAs_{y}Sb_{1-y}, the parameters x and y being selected from the interval 0.9 to 1.0, and
the third layer is partially disposed over the second layer and is made of a metal or an alloy.

15. The contact according to claim 14, wherein the substrate contains GaSb, InAs, GaInAsSb, AlGaAsSb, or a combination thereof.

16. The contact according to claim 15, wherein the substrate has a GaₓIn₁₋ₓAs_{y}Sb_{1-y} containing layer on a GaSb-containing layer.

17. The contact according to claim 14, wherein an anti-reflection layer is at least partially applied to the first layer in the areas that are not covered by the InₓGa₁₋ₓAs_{y}Sb_{1-y} containing second layer.

18. The contact according to claim 17, wherein the anti-reflection layer contains TaOₓ, TiO₂, MgF, ZnS, Al₂O₃, SiN, SiOₓ or a combination thereof.

19. The contact according to claim 17, wherein the anti-reflection layer comprises several layers.

20. The contact according to claim 14, wherein at least one layer made of a metal or an alloy contains gold, titanium, platinum, nickel, palladium, zinc, silver, germanium, or a combination thereof.

21. The contact according to claim 14, wherein the AlₙGa₁₋ₙAsₘSb₁₋ₘ containing material of the first layer and/or the InₓGa₁₋ₓAs_{y}Sb_{1-y} containing material of the second layer is provided with a doping material.

22. The contact according to claim 21, wherein the doping material is selected from silicon, sulfur, tellurium, carbon, magnesium, zinc, selenium, or a combination thereof.

23-26. (canceled)
